(19) United States
(12) Patent Application Publication
(10) Pub. No.: US 2024/0243740 A1
(43) Pub. Date: Jul. 18, 2024

(54) Higher-Voltage-Protected Transmission Gate to Prevent Unbalanced Aging Stress on Differential Receiver Input

(71) Applicant: Altera Corporation, San Jose, CA (US)

(72) Inventor: Chee Hong Aw, Bayan Lepas (MY)

(21) Appl. No.: 18/620,740

(22) Filed: Mar. 28, 2024

(51) Int. Cl. H03K 17/081; H04B 1/12

(52) U.S. Cl. CPC H03K 17/08104; H04B 1/12

(57) ABSTRACT

Integrated circuit devices, methods, and circuitry for selectively blocking a voltage signal on receiver circuitry to reduce or eliminate unequal aging on the receiver circuitry. A device may include a first input/output (IO) pin to receive a first voltage and a second IO pin to receive a second voltage. The device may include a differential signal receiver that includes a first terminal coupled to the first IO pin and a second terminal coupled to the second IO pin. Transmission gate circuitry may selectively block the first voltage or the second voltage from being applied to the differential signal receiver. The transmission gate circuitry may include transistors having a lower junction voltage limit than the first voltage or the second voltage, or both.

### BACKGROUND

The present disclosure relates generally to integrated circuit (IC) devices such as processors, application specific integrated circuits (ASICs), and programmable logic devices (PLDs) that support single-ended and low-voltage differential signaling (LVDS) communication on a single input.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are ubiquitous in modern electronics. Integrated circuits often communicate with other integrated circuits over input/output (IO) pins. Some integrated circuits communicate over IO pins that are configurable to use either single-ended or low-voltage differential signaling (LVDS). When the IO pins are configured for single-ended 3.3V Low Voltage Complementary Metal Oxide Semiconductor (LVCMOS) or Low Voltage Transistor-Transistor Logic (LVTTL), each pin has different input/output patterns. For example, one pin could have a static high for most of the time, whereas another pin could have a static low. Thus, the transistors connected to different pins will experience different levels of dynamic aging stress or static bias temperature instability (BTI) stress. After a certain period of usage, if two pins are re-configured to operate as a pair of differential LVDS pins, there may be a performance impact in terms of input offset and duty cycle distortion. This is because both input devices of the LVDS Receiver (Rx) shared by the IO pins has undergone different aging conditions due to the static signal values. This is especially problematic and may be become a limiter if the IO pins are intended to support higher-bandwidth LVDS data rates (e.g., greater than 1 Gbps).

### BRIEF DESCRIPTION OF THE DRAWINGS

Various aspects of this disclosure may be better understood upon reading the following detailed description and upon reference to the drawings in which:

FIG. 1 illustrates a block diagram of a system that may configure input/output (IO) pins of an integrated circuit device to operate as single-ended or low-voltage differential signaling (LVDS) pins;

FIG. 2 illustrates an example of the integrated circuit device as a programmable logic device, such as a field-programmable gate array (FPGA);

FIG. 3 is a block diagram of receiver circuitry for an IO pin pair that supports two single-ended or LVDS IO pin configurations with higher-voltage transmission gate circuitry to protect the LVDS receiver while the IO pin configuration is single-ended;

FIG. 4 is a circuit diagram of the higher-voltage transmission gate circuitry;

FIG. 5 is a circuit diagram of the higher-voltage transmission gate circuitry operating in a pass-through LVDS state while receiving a 0V input;

FIG. 6 is a circuit diagram of the higher-voltage transmission gate circuitry operating in a pass-through LVDS state while receiving a 3.3V input;

FIG. 7 is a circuit diagram of the higher-voltage transmission gate circuitry operating in a blocking (single-ended) state while receiving a 0V input;

FIG. 8 is a circuit diagram of the higher-voltage transmission gate circuitry operating in a blocking (single-ended) state while receiving a 3.3V input; and

FIG. 9 is a block diagram of a data processing system incorporating the higher-voltage transmission gate circuitry.

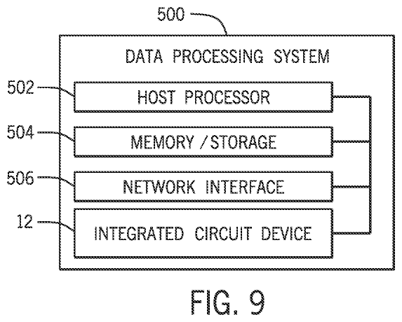

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

This disclosure relates to higher-voltage transmission gate circuitry that protects a low-voltage differential signaling (LVDS) receiver from unbalanced aging stress. Indeed, many integrated circuits, such as programmable logic devices, have input/output (IO) pins that are configurable to communicate using either single-ended or low-voltage differential signaling (LVDS). Pairs of IO pins may be configured using configuration data to operate as two single-ended communication pins or as a single pair of LVDS pins. Each pin may have its own single-ended receiver circuitry to receive single-ended communication and may share an LVDS receiver that detects the output based on the differential signal across the two pins. As mentioned above, when the IO pins are configured for single-ended 3.3V Low Voltage Complementary Metal Oxide Semiconductor (LVCMOS) or Low Voltage Transistor-Transistor Logic (LVTTL), each pin receives a signal with different input/output patterns. As a consequence, this may unequally stress the shared LVDS receiver. For example, one pin could have a static high for most of the time, whereas another pin could have a static low. Thus, the transistors of the shared LVDS receiver connected to different pins will experience different levels of dynamic aging stress or static bias temperature instability (BTI) stress. After a certain period of usage, if the two pins are re-configured to operate as a pair of differential LVDS pins, the LVDS receiver may not perform as desired due to the differential aging on different transistors of the LVDS receiver. This is especially problematic and may be become a limiter if the IO pins are intended to support higher-bandwidth LVDS data rates (e.g., greater than 1 Gbps).

Complicating the situation is that advanced integrated circuit fabrication process nodes produce integrated circuit transistors that operate at increasingly lower voltages. Indeed, whereas LVDS communication often involves signals of 2.5V, 3.0V and 3.3V, even thick-gate transistors may support up to about 1.8V of junction voltage, which is much lower than the signal values. What is more, beyond this limit, there may be an electrical overstress (EOS) violation.

Accordingly, this disclosure introduces a higher-voltage transmission gate to protect the LVDS receiver from being subject to unequal signals while an IO pin pair is operating in a single-ended state. The higher-voltage transmission gate may include multiple lower-voltage transistors that receive protection voltages to prevent the junction voltage from exceeding a junction voltage limit (e.g., for many advanced process nodes, 1.8V). These protection voltages ensure the that the lower-voltage transistors are protected even while blocking higher-voltage single-ended signals or passing higher-voltage LVDS signals (e.g., of 3.3V).

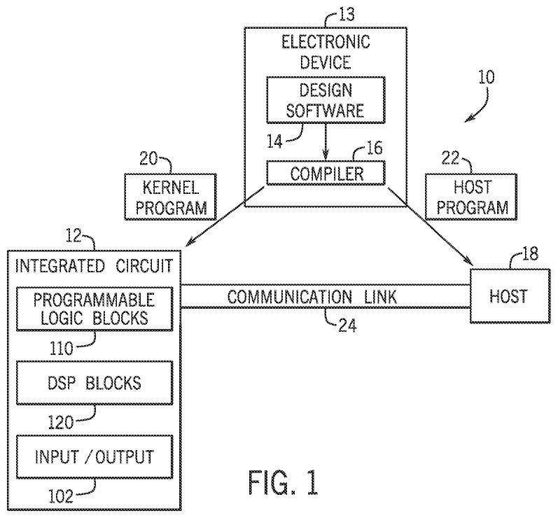

With the foregoing in mind, FIG. 1 illustrates a block diagram of one example of a system 10 that may be used to configure an integrated circuit device 12 with configurable IO pins that may receive single-ended or LVDS signals while protecting against unequal stress on the LVDS receiver. A designer may desire to implement a system on the integrated circuit device 12 (e.g., a programmable logic device such as a field-programmable gate array (FPGA), an application-specific integrated circuit (ASIC) that includes programmable logic circuitry, or an application-specific integrated circuit (ASIC) that is to be fabricated). The integrated circuit device 12 may include a single integrated circuit, multiple integrated circuits in a package (e.g., a multi-chip module (MCM), a system-in-package (SiP)), or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12 or in a design phase of the integrated circuit device 12, a designer may use an electronic device 13 (e.g., a computer) to implement high-level designs (e.g., a system user design) using design software 14, such as a version of INTEL® QUARTUS® by INTEL CORPORATION. Additionally or alternatively, the electronic device 13 may use the design software 14 and a compiler 16 to convert a high-level program into a lower-level description (e.g., a configuration program, a bitstream). The compiler 16 may provide machine-readable instructions representative of the high-level program to a host 18 and the integrated circuit device 12. The host 18 may receive a host program 22 that may be implemented by the kernel programs 20. To implement the host program 22, the host 18 may communicate instructions from the host program 22 to the integrated circuit device 12 via a communications link 24 that may be, for example, direct memory access (DMA) communications or peripheral component interconnect express (PCIe) communications. In some embodiments, the kernel programs 20 and the host 18 may enable configuration of circuits including configurable IO pins 102, programmable logic blocks 110, and digital signal processing (DSP) blocks 120 on the integrated circuit device 12. Pairs of the IO pins 102 may be configured to operate as single-ended pins that receive unique signals on separate single-ended receivers or as an LVDS pair that receives a differential signal on a receiver shared by the IO pin pair. The programmable logic blocks 110 may include circuitry and/or other logic elements and may be configurable to implement a variety of functions in combination with digital signal processing (DSP) blocks 120.

The DSP blocks 120 may include circuitry to carry out operations that involve multiplication, such as to perform multiply-accumulate operations or matrix-matrix or matrix-vector multiplication. The integrated circuit device 12 may include many (e.g., hundreds or thousands) of the DSP blocks 120. Additionally, the DSP blocks 120 may be communicatively coupled to another such that data output from one DSP block 120 may be provided to other DSP blocks 120. A DSP block 120 may include hardened arithmetic circuitry that is purpose-built for performing arithmetic operations. The hardened arithmetic circuitry of the DSP blocks 120 may be contrasted with arithmetic circuitry that may be constructed in soft logic in the programmable logic circuitry (e.g., the programmable logic blocks 110). While circuitry for performing the same arithmetic operations may be programmed into the programmable logic circuitry (e.g., the programmable logic blocks 110), doing this may take up significantly more die area, may consume more power, and/or may consume more processing time.

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting.

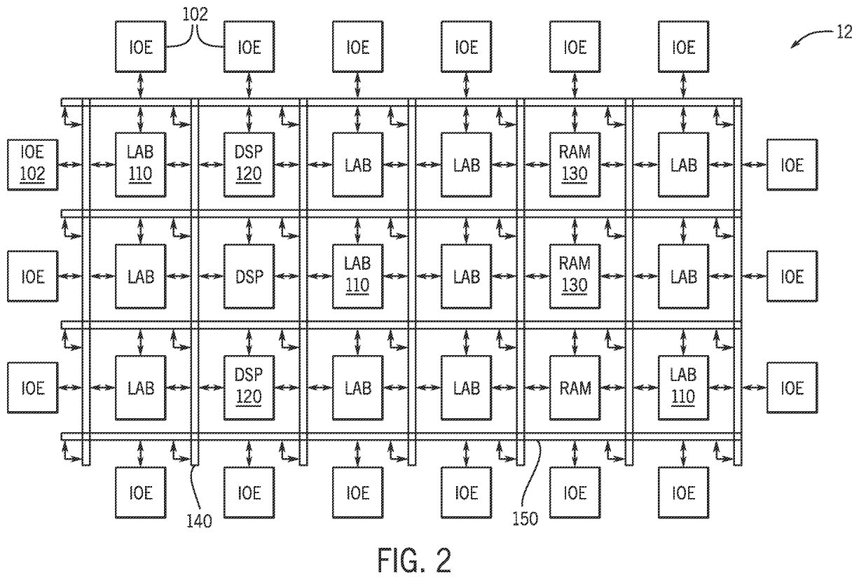

An illustrative example of a programmable integrated circuit device 12 such as a programmable logic device (PLD) that may be configured to implement a circuit design is shown in FIG. 2. As shown in FIG. 2, the integrated circuit device 12 (e.g., a field-programmable gate array integrated circuit die) may include a two-dimensional array of functional blocks, including programmable logic blocks 110 (also referred to as logic array blocks (LABs) or configurable logic blocks (CLBs)) and other functional blocks, such as random-access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals. LABs 110 may also be grouped into larger programmable regions sometimes referred to as logic sectors that are individually managed and configured by corresponding logic sector managers. The grouping of the programmable logic resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy.

Programmable logic circuitry of the integrated circuit device 12 may include programmable memory elements, which are sometimes referred to as configuration random access memory (CRAM). The memory elements may be loaded with configuration data (also called programming data or configuration bitstream) using input-output (IO) pins 102. Once loaded, the memory elements each provide a corresponding static control signal that controls the operation of an associated functional block (e.g., LABs 110, DSP 120, RAM 130, or input-output elements 102).

In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration random-access memory (CRAM), or programmable memory elements.

Programmable logic device (PLD) 100 may be configured to implement a custom circuit design. For example, the configuration RAM may be programmed such that LABs 110, DSP 120, and RAM 130, programmable interconnect circuitry (i.e., vertical channels 140 and horizontal channels 150), and the input-output elements 102 form the circuit design implementation.

In addition, the programmable logic device may have input-output (IO) pins 102 for driving signals off of the integrated circuit device 12 and for receiving signals from other devices. Input-output elements 102 may include parallel input-output circuitry, serial data transceiver circuitry, differential receiver and transmitter circuitry, or other circuitry used to connect one integrated circuit to another integrated circuit. Pairs of the IO pins 102 may be configured to operate as single-ended pins that receive unique signals on separate single-ended receivers or as an LVDS pair that receives a differential signal on a receiver shared by the IO pin pair.

The integrated circuit device 12 may also include programmable interconnect circuitry in the form of vertical routing channels 140 (i.e., interconnects formed along a vertical axis of the integrated circuit 100) and horizontal routing channels 150 (i.e., interconnects formed along a horizontal axis of the integrated circuit 100), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that routing topologies other than the topology of the interconnect circuitry depicted in FIG. 1 may be used. For example, the routing topology may include wires that travel diagonally or that travel horizontally and vertically along different parts of their extent as well as wires that are perpendicular to the device plane in the case of three-dimensional integrated circuits, and the driver of a wire may be located at a different point than one end of a wire. The routing topology may include global wires that span substantially all of the integrated circuit device 12, fractional global wires such as wires that span part of the integrated circuit device 12, staggered wires of a particular length, smaller local wires, or any other suitable interconnection resource arrangement. The integrated circuit device 12 may be programmed to perform a wide variety of operations and receive data from other devices.

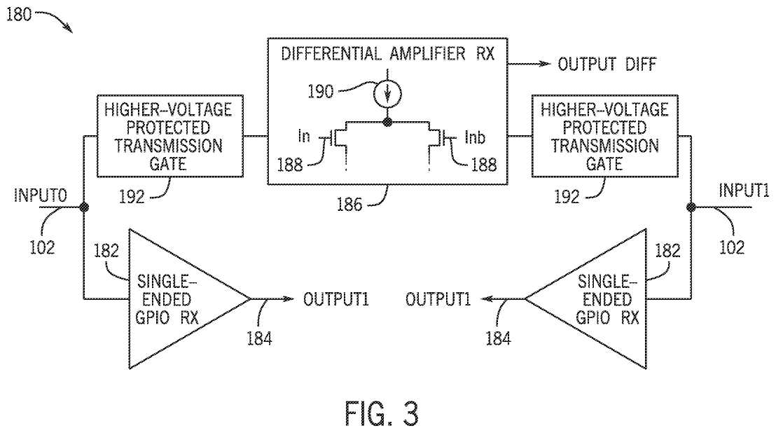

Indeed, to receive data from other devices, the IO pins 102 may be configurable in pairs to operate in a single-ended state or a differential signaling state (e.g., a low-voltage differential signaling (LVDS) state). An example of IO pair receiver circuitry 180 appears in FIG. 3, which illustrates how two input pins 102 that receive voltage signals “Input0” and “Input1” can generate either two independent single-ended outputs or one differential signaling output. In the single-ended state, the single-ended GPIO receivers (Rx) 182 convert the “Input” and “Input1” signals into output signals “Output0” and “Output1” signals, respectively. Because the “Input0” and “Input1” signals are independent, the voltage values of these signals may be the same or may be different. While in the differential signaling state, the input signals “Input0” and “Input1” are differential to one another (e.g., for LVDS signals, either 0V and 3.3V or 3.3V and 0V). A differential amplifier receiver (Rx) 186 that is shared between the input pins 102 receives the input signal “Input0” as an input “In” and receives the input signal “Input1” as an input “Inb” on respective input terminals 188. Using a current source 190 that selectively drives part of the differential amplifier Rx 186 based on the values of “In” and “Inb,” the differential amplifier Rx 186 may generate a differential output “OutputDiff.”

Since the IO pair receiver circuitry 180 is shared by two pins 102 that sometimes operate in the single-ended state, it is possible that the inputs “Input0” or “Input1” could be static voltages that are held for extended periods of time. Since the inputs “Input0” and “Input1” are independent in the single-ended state, in some cases, the values of inputs “Input0” or “Input1” could be different for long periods of time. Thus, if the inputs “Input0” or “Input1” were applied to the input terminals 188 differential amplifier Rx 186 while the IO pair receiver circuitry 180 is in the single-ended state, the input terminals 188 could experience drastically different levels of dynamic aging stress or static bias temperature instability (BTI) stress. After a certain period of usage, if the IO pins 102 are re-configured to operate as a pair of differential signaling (e.g., LVDS) pins, there may be a performance impact in terms of input offset and duty cycle distortion. To avoid unequal aging like this, the input signals “Input0” and “Input1” may be blocked from reaching the input terminals 188 of the differential amplifier Rx 186.

Complicating the situation is that advanced integrated circuit fabrication process nodes produce integrated circuit transistors that operate at increasingly lower voltages. Indeed, whereas LVDS communication often involves signals of 2.5V, 3.0V and 3.3V, even thick-gate transistors may support up to about 1.8V of junction voltage, which is much lower than the signal values. What is more, beyond this limit, there may be an electrical overstress (EOS) violation. Accordingly, the IO pair receiver circuitry 180 may include higher-voltage transmission gate circuitry 192 that may protect the differential amplifier Rx 186 from being subject to unequal signals while the IO pair receiver circuitry 180 is operating in a single-ended state. The higher-voltage transmission gate circuitry 192 may be placed in an “OFF” state to block the input signals “Input0” and “Input1” from reaching the input terminals 188 of the differential amplifier Rx 186 while the IO pair receiver circuitry 180 is operating in a single-ended state. The higher-voltage transmission gate circuitry 192 may be placed in an “ON” state to allow the input signals “Input0” and “Input1” to pass through to the input terminals 188 of the differential amplifier Rx 186 while the IO pair receiver circuitry 180 is operating in a differential signaling state. The higher-voltage transmission gate circuitry 192 may include multiple lower-voltage transistors that receive protection voltages to prevent the junction voltage from exceeding a junction voltage limit (e.g., for many advanced process nodes, 1.8V). These protection voltages ensure the that the lower-voltage transistors are protected even while blocking higher-voltage single-ended signals or passing higher-voltage LVDS signals (e.g., of 3.3V).

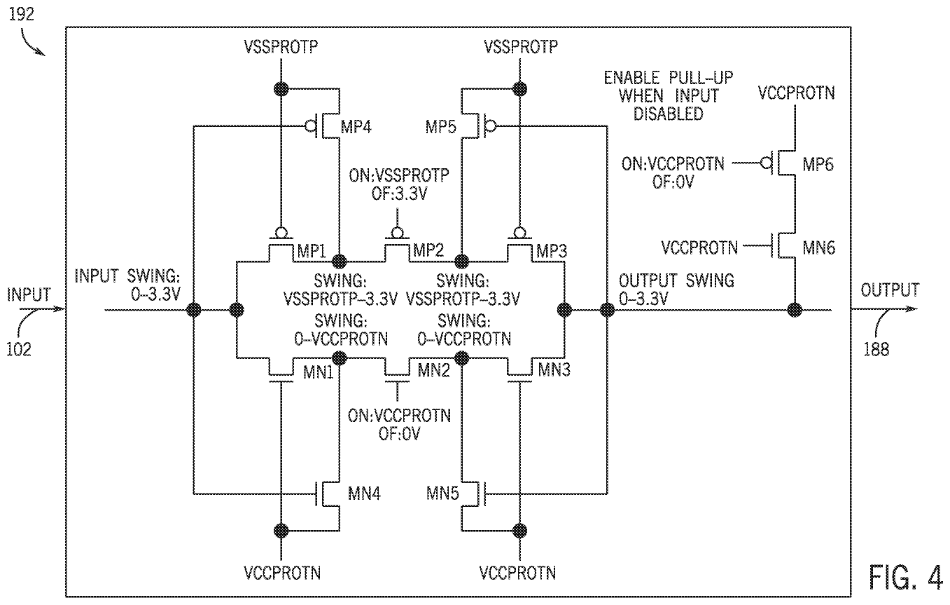

One example circuit diagram of the higher-voltage transmission gate circuitry 192 is shown in FIG. 4. The higher-voltage transmission gate circuitry 192 shown in FIG. 4 provides an example where the transistors have a junction voltage limit of 1.8V, the maximum expected voltage of the input signal from the input pin 102 is 3.3V and the minimum expected voltage of the input signal from the input pin 102 is 0V. As such, protection voltages vssprotp and vccprotn are used by the higher-voltage transmission gate circuitry 192 to ensure that the junction voltage across any transistor of the higher-voltage transmission gate circuitry 192 remains beneath the junction voltage limit. However, the principles of the higher-voltage transmission gate circuitry 192 may extend to any suitable voltages. For example, if there were an advanced integrated circuit process node where the junction voltage limit is 1.2V and there were an IO specification where the maximum voltage swing is 2.0V, the protection voltages vssprotp and vccprotn may be selected to prevent the transistors of the higher-voltage transmission gate circuitry 192 from exceeding this other junction voltage limit. This should be kept in mind while considering the explanation of the higher-voltage transmission gate circuitry 192 of FIG. 4.

In the example of FIG. 4, the higher-voltage transmission gate circuitry 192 operates as a 3.3V-protected transmission gate having an NMOS path and a PMOS path. In advanced integrated circuits that support 3.3V communication, the protection voltage vccprotn may be selected to protect the NMOS path through the higher-voltage transmission gate circuitry 192 at a voltage of about 1.8V. The protection voltage vssprotp may be selected to protect the PMOS path through the higher-voltage transmission gate circuitry 192 at a voltage of about 1.5V (e.g., any suitable non-zero vss, which maybe about 0.46*3.3V=˜1.5V). These protection voltages protect the transistors in the higher-voltage transmission gate circuitry 192 while receiving signals with swings of 3.3V. This is because even thick-gate transistors normally support up to about 1.8V of junction voltage EOS limit. These protection voltages ensure that the transistors are protected.

The higher-voltage transmission gate circuitry 192 may include a number of transistors. The NMOS transistors include transistors MN1, MN2, MN3, MN4, MN5, and MN6 and the PMOS transistors include transistors MP1, MP2, MP3, MP4, MP5, and MP6. The transistors MP2 & MN2 are the main switching devices to control whether the path from input to output is ON or OFF. The PMOS transistors MP1 & MP3 ensure that the nodes around MP2 swing within vssprotp-3.3V and never go lower than vssprotp, which would create a junction voltage greater 1.8V. The PMOS transistors MP4 & MP5 are pull-up devices to further ensure that the nodes around MP2 are capped at a vssprotp minimum voltage level, even though there is leakage when the input is static at 0. Similarly, the NMOS transistors MN1 & MN3 ensure that the nodes around MN2 swing within 0-vccprotn and never go higher than vccprotn, which would also create a junction voltage >1.8V. The NMOS transistors MN4 & MN5 pull-up device are there to further ensure that the nodes around MN2 are capped at vccprotn maximum voltage level even when input is static at 3.3V.

The transistors MN6 & MP6 are pull-up devices to pull-up the floating output node (when transmission gate is turned OFF) to close to vccprotn. This is to set voltage at both input terminals 188 of the differential amplifier Rx 186 to the same voltage potential, thereby preventing unbalanced aging stress when the differential amplifier Rx 186 is disabled. Please take note that this new design does not impact the ESD protection at the input pin.

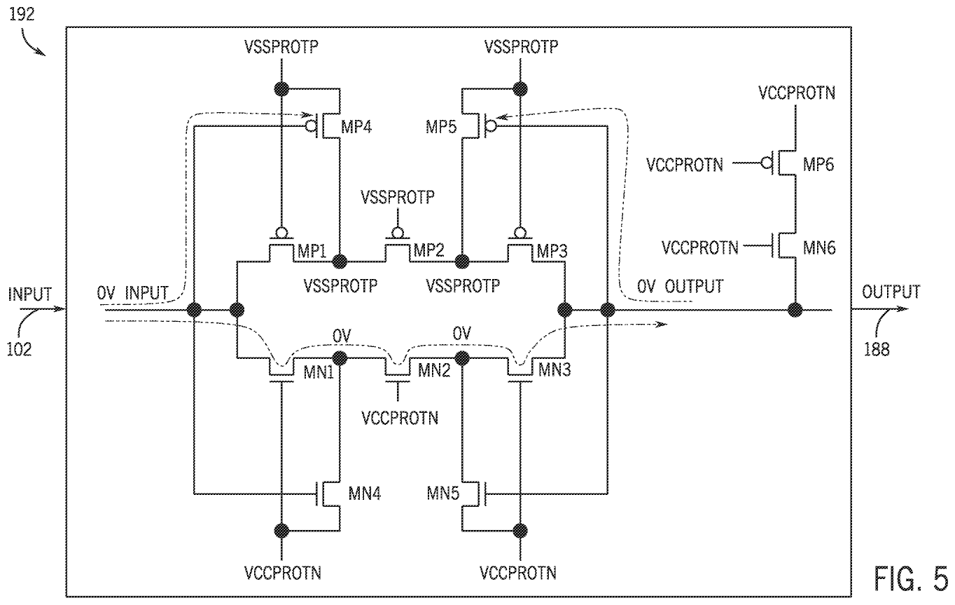

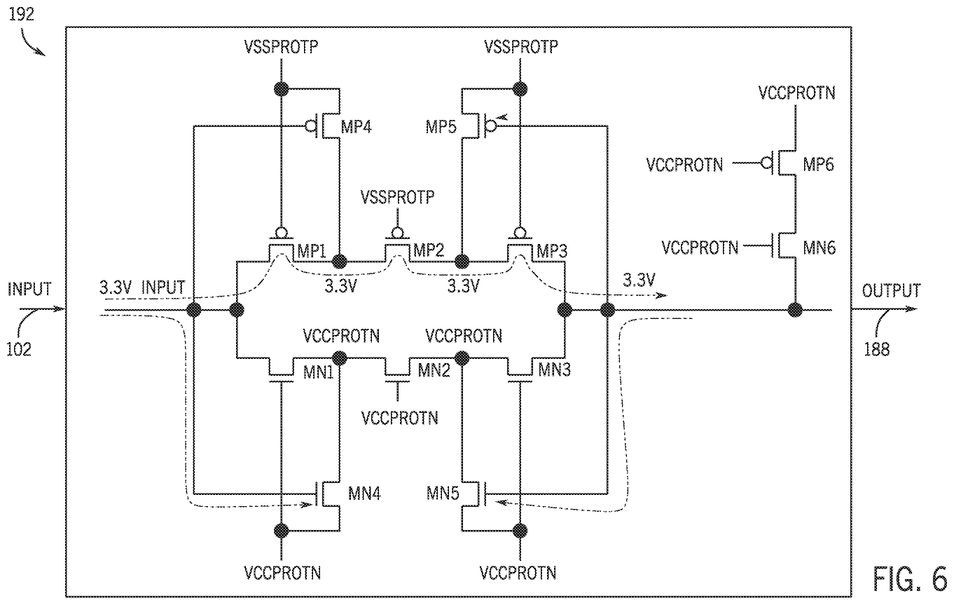

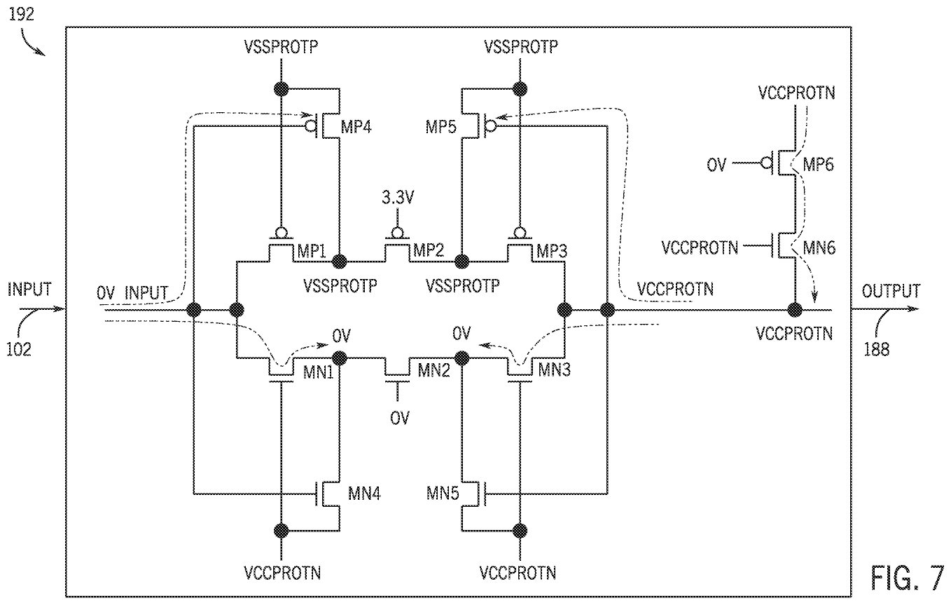

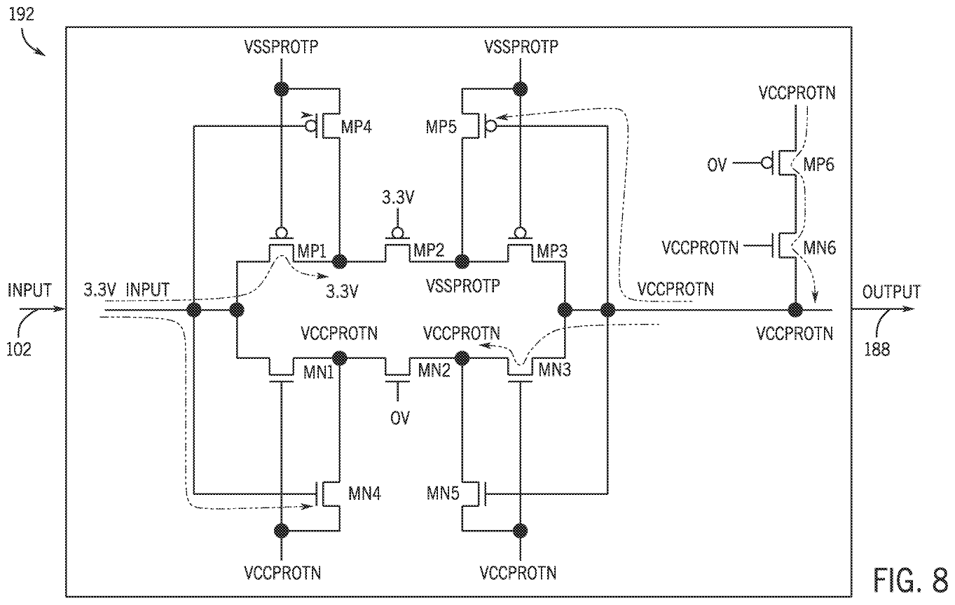

With the higher-voltage (e.g., 3.3V) protection mechanism, the higher-voltage transmission gate circuitry 192 can operate properly without EOS risk whether in an ON of OFF state. FIGS. 5 and 6 illustrate operation in the “ON” state and FIGS. 7 and 8 illustrate operation in the “OFF” state.

FIG. 5 illustrates the condition where the higher-voltage transmission gate circuitry 192 is in the “ON” state and the input voltage is 0V. Here, the NMOS path through the NMOS devices MN1, MN2, and MN3 passes the low-voltage signal of 0V received from the input pin 102 because 0V is less than the protection voltage vccprotn that is applied to the gates of the MN1, MN2, and MN3 transistors. At the same time, the PMOS transistor MP4 passes the protection voltage vssprotp to the voltage node between the transistors MP1 and MP2 and the PMOS transistor MP5 passes the protection voltage vssprotp to the voltage node between the transistors MP2 and MP3, ensuring that the voltage difference across the transistors MP1 or MP3 do not exceed 1.8V.

FIG. 6 illustrates the condition where the higher-voltage transmission gate circuitry 192 is in the “ON” state and the input voltage is 3.3V. Here, the PMOS path through the PMOS devices MP1, MP2, and MP3 passes the higher-voltage signal of 3.3V received from the input pin 102 because 3.3V is greater than the protection voltage vssprotp that is applied to the gates of the MP1, MP2, and MP3 transistors. At the same time, the NMOS transistor MN4 passes the protection voltage vccprotn to the voltage node between the transistors MN1 and MN2 and the NMOS transistor MN5 passes the protection voltage vccprotn to the voltage node between the transistors MN2 and MN3, ensuring that the voltage difference across the transistors MN1 or MN3 do not exceed 1.8V.

FIG. 7 illustrates the condition where the higher-voltage transmission gate circuitry 192 is in the “OFF” state and the input voltage is 0V. Here, the NMOS path through the NMOS devices MN1, MN2, and MN3 is blocked at the NMOS transistor MN2. This is because the gate of the NMOS transistor MN2 is supplied with 0V, and thus the transistor MN2 does not activate. What is more, the gate of the pulldown transistor MP6 is coupled to 0V and the gate of the pulldown transistor MN6 is coupled to vccprotn. This causes the pulldown transistors MN6 and MP6 to pull down the output voltage to vccprotn, which is applied to the input terminal 188 of the differential amplifier Rx 186. The transistor MN3 also passes the protection voltage vccprotn to the voltage node between the transistor MN2 and MN3, which ensures that the voltage difference across the transistor MN2 is less than the junction voltage limit of 1.8V. The protection voltage vccprotn is also coupled to the gate of the PMOS transistor MP5, causing it to pull down the PMOS protection voltage vssprotp to the voltage node between the transistors MP2 and MP3. Therefore, the transistors of the higher-voltage transmission gate circuitry 192 remain protected within the junction limit (e.g., 1.8V) while also blocking the input voltage. the low-voltage signal of 0V received from the input pin 102 because 0V is less than the protection voltage vccprotn that is applied to the gates of the MN1, MN2, and MN3 transistors. At the same time, the PMOS transistor MP4 passes the protection voltage vssprotp to the voltage node between the transistors MP1 and MP2 and the PMOS transistor MP5 passes the protection voltage vssprotp to the voltage node between the transistors MP2 and MP3, ensuring that the voltage difference across the transistors MP1 or MP3 do not exceed 1.8V.

FIG. 8 illustrates the condition where the higher-voltage transmission gate circuitry 192 is in the “OFF” state and the input voltage is 3.3V. Here, the PMOS path through the PMOS devices MP1, MP2, and MP3 is blocked at the PMOS transistor MP2. This is because the gate of the PMOS transistor MP2 is supplied with 3.3V, and thus the transistor MP2 does not activate. What is more, the gate of the pulldown transistor MP6 is coupled to 0V and the gate of the pulldown transistor MN6 is coupled to vccprotn. This causes the pulldown transistors MN6 and MP6 to pull down the output voltage to vccprotn, which is applied to the input terminal 188 of the differential amplifier Rx 186. In other words, the voltage value applied to the input terminal 188 of the differential amplifier Rx 186 remains the same regardless of the input voltage while the higher-voltage transmission gate circuitry 192 is in the “OFF” state.

Continuing with the example of FIG. 8, the transistor MN3 also passes the protection voltage vccprotn to the voltage node between the transistor MN2 and MN3, which ensures that the voltage difference across the transistor MN2 is less than the junction voltage limit of 1.8V. The protection voltage vccprotn is also coupled to the gate of the PMOS transistor MP5, causing it to pull down the PMOS protection voltage vssprotp to the voltage node between the transistors MP2 and MP3. This ensures that the voltage difference across the transistor MP2 remains less than 1.8V (here, 3.3V-vssprotp, or just under 1.8V) Therefore, the transistors of the higher-voltage transmission gate circuitry 192 remain protected within the junction limit (e.g., 1.8V) while also blocking the input voltage, whether the input voltage is 0V or 3.3V.

An integrated circuit including the higher-voltage transmission gate circuitry of this disclosure may be a component included in a data processing system, such as a data processing system 500, shown in FIG. 14. The data processing system 500 may include the integrated circuit system 12 (e.g., a programmable logic device), a host processor 502, memory and/or storage circuitry 504, or a network interface 506. The multiplier circuitry of this disclosure may be part of the integrated circuit system 12 (e.g., a programmable logic device), the host processor 502, the memory and/or storage circuitry 504, or the network interface 506, or another integrated circuit such as a graphics processing unit (GPU) or AI application specific integrated circuit (ASIC). The data processing system 500 may include more or fewer components (e.g., electronic display, user interface structures, application specific integrated circuits (ASICs)). The integrated circuit device 12 may be used to efficiently implement a symmetric FIR filter or perform complex multiplication. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit device 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as different cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit device comprising:
a first input/output (IO) pin to receive a first voltage;
a second IO pin to receive a second voltage;
a differential signal receiver comprising a first terminal coupled to the first IO pin and a second terminal coupled to the second IO pin; and
transmission gate circuitry to selectively block the first voltage or the second voltage from being applied to the differential signal receiver, wherein the transmission gate circuitry comprises transistors having a lower junction voltage limit than the first voltage or the second voltage, or both.

EXAMPLE EMBODIMENT 2. The integrated circuit device of example embodiment 1, wherein the first IO pin and the second IO pin are configurable to operate, in a first state, as individual single-ended IO pins in which the first voltage and the second voltage are independent and, in a second state, as a pair of differential IO pins in which the first voltage and the second voltage carry a differential signal.

EXAMPLE EMBODIMENT 3. The integrated circuit device of example embodiment 2, wherein the transmission gate circuitry is to selectively block the first voltage and the second voltage from being applied to the differential signal receiver while the first IO pin and the second IO pin are configured to operate as individual single-ended IO pins.

EXAMPLE EMBODIMENT 4. The integrated circuit device of example embodiment 1, wherein the differential signal receiver is to receive a low-voltage differential signaling (LVDS) signal based on the first voltage on the first IO pin and the second voltage on the second IO pin.

EXAMPLE EMBODIMENT 5. The integrated circuit device of example embodiment 1, wherein the LVDS signal has a maximum voltage difference of 3.3V.

EXAMPLE EMBODIMENT 6. The integrated circuit device of example embodiment 1, wherein the first voltage or the second voltage, or both, exceed 1.8V at least occasionally and wherein the transistors of the transmission gate circuitry comprise a junction voltage limit of 1.8V.

EXAMPLE EMBODIMENT 7. The integrated circuit device of example embodiment 6, wherein the first voltage or the second voltage, or both, reach 2.5V at least occasionally.

EXAMPLE EMBODIMENT 8. The integrated circuit device of example embodiment 6, wherein the first voltage or the second voltage, or both, reach 3.0V at least occasionally.

EXAMPLE EMBODIMENT 9. The integrated circuit device of example embodiment 6, wherein the first voltage or the second voltage, or both, reach 3.3V at least occasionally.

EXAMPLE EMBODIMENT 10. The integrated circuit device of example embodiment 1, wherein the integrated circuit device comprises a programmable logic device.

EXAMPLE EMBODIMENT 11. An article of manufacture comprising tangible, non-transitory, computer-readable media comprising instructions that, when executed by a data processing system, cause operations comprising:
configuring a pair of input/output (IO) pins of an integrated circuit device to operate as single-ended IO pins, wherein the pair of IO pins are coupled to respective single-ended receiver circuits and a shared low-voltage differential signaling (LVDS) receiver circuit; and
configuring transmission gate circuitry to selectively block voltages from the pair of IO pins from reaching the shared LVDS receiver circuit to reduce unequal aging on the shared LVDS receiver circuit while the pair of IO pins operate as single-ended IO pins, wherein the transmission gate circuitry comprises transistors having a lower junction voltage limit than a highest value of the voltages from the pair of IO pins.

EXAMPLE EMBODIMENT 12. The article of manufacture of example embodiment 11, wherein configuring the transmission gate circuitry to selectively block the voltages from the pair of IO pins from reaching the shared LVDS receiver comprises applying the highest value of the voltages from the pair of IO pins to a first transistor of the transmission gate circuitry and a first protection voltage on a first voltage node between the first transistor and a second transistor of the transmission gate circuitry, wherein a difference between the highest value of the voltages from the pair of IO pins and the first protection voltage is less than or equal to the junction voltage limit, and wherein a difference between the lowest value of the voltages from the pair of IO pins and the first protection voltage is less than or equal to the junction voltage limit.

EXAMPLE EMBODIMENT 13. The article of manufacture of example embodiment 12, wherein configuring the transmission gate circuitry to selectively block the voltages from the pair of IO pins from reaching the shared LVDS receiver comprises applying a lowest value of the voltages from the pair of IO pins to a third transistor of the transmission gate circuitry and a second protection voltage on a second voltage node between the third transistor and a fourth transistor of the transmission gate circuitry, wherein a difference between the lowest value of the voltages from the pair of IO pins and the second protection voltage is less than or equal to the junction voltage limit, and wherein a difference between the highest value of the voltages from the pair of IO pins and the second protection voltage is less than or equal to the junction voltage limit.

EXAMPLE EMBODIMENT 14. The article of manufacture of example embodiment 13, wherein the junction voltage limit of the transistors is 1.8V, the first protection voltage or the second protection voltage is between 1.5V and 1.8V, and the highest value of the voltages from the pair of IO pins is 3.3V.

EXAMPLE EMBODIMENT 15. The article of manufacture of example embodiment 13, wherein configuring the transmission gate circuitry comprises applying the first protection voltage to the first voltage node between the first transistor and the second transistor, wherein the first transistor and the second transistor are NMOS transistors, and applying the second protection voltage to the second voltage node between the third transistor and the fourth transistor, wherein the third transistor and the fourth transistor are PMOS transistors.

EXAMPLE EMBODIMENT 16. Transmission gate circuitry to prevent aging stress on receiving circuitry by selectively blocking a voltage from an input/output (IO) pin from reaching a terminal of the receiver circuitry, the transmission gate circuitry comprising:
an NMOS path comprising NMOS transistors to which a first protection voltage is selectively applied at voltage nodes between the NMOS transistors to prevent a junction voltage difference between the NMOS transistors from exceeding a junction voltage limit; and
a PMOS path comprising PMOS transistors to which a second protection voltage is selectively applied at voltage nodes between the PMOS transistors to prevent a junction voltage difference between the PMOS transistors from exceeding the junction voltage limit.

EXAMPLE EMBODIMENT 17. The transmission gate circuitry of example embodiment 16, wherein the NMOS path and the PMOS path couple to the IO pin on one end and to the terminal of the receiver circuitry on another end.

EXAMPLE EMBODIMENT 18. The transmission gate circuitry of example embodiment 17, wherein:
the NMOS path comprises:
a first NMOS transistor coupled between the IO pin and a second NMOS transistor;
a third NMOS transistor coupled between the second NMOS transistor and the terminal of the receiver circuitry; and
a fourth NMOS transistor coupled between the first protection voltage and a first NMOS voltage node between the first NMOS transistor and the second NMOS transistor, wherein a gate of the fourth NMOS transistor is coupled to the IO pin; and
the PMOS path comprises:
a first PMOS transistor coupled between the IO pin and a second PMOS transistor;
a third PMOS transistor coupled between the second PMOS transistor and the terminal of
the receiver circuitry; and
a fourth PMOS transistor coupled between the second protection voltage and a first PMOS voltage node between the first PMOS transistor and the second PMOS transistor, wherein a gate of the fourth PMOS transistor is coupled to the IO pin.

EXAMPLE EMBODIMENT 19. The transmission gate circuitry of example embodiment 18, wherein:
the NMOS path comprises a fifth NMOS transistor coupled between the first protection voltage and a second NMOS voltage node between the second NMOS transistor and the third NMOS transistor, wherein a gate of the fifth PMOS transistor is coupled to the terminal of the receiver circuitry; and
the PMOS path comprises a fifth PMOS transistor coupled between the second protection voltage and a second PMOS voltage node between the second PMOS transistor and the third PMOS transistor, wherein a gate of the fifth PMOS transistor is coupled to the terminal of the receiver circuitry.

EXAMPLE EMBODIMENT 20. The transmission gate circuitry of example embodiment 19, comprising pull-down transistors coupled in series between the first protection voltage and the terminal of the receiver circuitry, wherein the pull-down transistors are to provide the first protection voltage to the terminal of the receiver circuitry while the IO pin is in a single-ended communication state but not when the IO pin is in a low-voltage differential signaling (LVDS) state.

What is claimed is:

1. An integrated circuit device comprising:
a first input/output (IO) pin to receive a first voltage;
a second IO pin to receive a second voltage;
a differential signal receiver comprising a first terminal coupled to the first IO pin and a second terminal coupled to the second IO pin; and
transmission gate circuitry to selectively block the first voltage or the second voltage from being applied to the differential signal receiver, wherein the transmission gate circuitry comprises transistors having a lower junction voltage limit than the first voltage or the second voltage, or both.

2. The integrated circuit device of claim 1, wherein the first IO pin and the second IO pin are configurable to operate, in a first state, as individual single-ended IO pins in which the first voltage and the second voltage are independent and, in a second state, as a pair of differential IO pins in which the first voltage and the second voltage carry a differential signal.

3. The integrated circuit device of claim 2, wherein the transmission gate circuitry is to selectively block the first voltage and the second voltage from being applied to the differential signal receiver while the first IO pin and the second IO pin are configured to operate as individual single-ended IO pins.

4. The integrated circuit device of claim 1, wherein the differential signal receiver is to receive a low-voltage differential signaling (LVDS) signal based on the first voltage on the first IO pin and the second voltage on the second IO pin.

5. The integrated circuit device of claim 1, wherein the LVDS signal has a maximum voltage difference of 3.3V.

6. The integrated circuit device of claim 1, wherein the first voltage or the second voltage, or both, exceed 1.8V at least occasionally and wherein the transistors of the transmission gate circuitry comprise a junction voltage limit of 1.8V.

7. The integrated circuit device of claim 6, wherein the first voltage or the second voltage, or both, reach 2.5V at least occasionally.

8. The integrated circuit device of claim 6, wherein the first voltage or the second voltage, or both, reach 3.0V at least occasionally.

9. The integrated circuit device of claim 6, wherein the first voltage or the second voltage, or both, reach 3.3V at least occasionally.

10. The integrated circuit device of claim 1, wherein the integrated circuit device comprises a programmable logic device.

11. An article of manufacture comprising tangible, non-transitory, computer-readable media comprising instructions that, when executed by a data processing system, cause operations comprising:
configuring a pair of input/output (IO) pins of an integrated circuit device to operate as single-ended IO pins, wherein the pair of IO pins are coupled to respective single-ended receiver circuits and a shared low-voltage differential signaling (LVDS) receiver circuit; and
configuring transmission gate circuitry to selectively block voltages from the pair of IO pins from reaching the shared LVDS receiver circuit to reduce unequal aging on the shared LVDS receiver circuit while the pair of IO pins operate as single-ended IO pins, wherein the transmission gate circuitry comprises transistors having a lower junction voltage limit than a highest value of the voltages from the pair of IO pins.

12. The article of manufacture of claim 11, wherein configuring the transmission gate circuitry to selectively block the voltages from the pair of IO pins from reaching the shared LVDS receiver comprises applying the highest value of the voltages from the pair of IO pins to a first transistor of the transmission gate circuitry and a first protection voltage on a first voltage node between the first transistor and a second transistor of the transmission gate circuitry, wherein a difference between the highest value of the voltages from the pair of IO pins and the first protection voltage is less than or equal to the junction voltage limit, and wherein a difference between the lowest value of the voltages from the pair of IO pins and the first protection voltage is less than or equal to the junction voltage limit.

13. The article of manufacture of claim 12, wherein configuring the transmission gate circuitry to selectively block the voltages from the pair of IO pins from reaching the shared LVDS receiver comprises applying a lowest value of the voltages from the pair of IO pins to a third transistor of the transmission gate circuitry and a second protection voltage on a second voltage node between the third transistor and a fourth transistor of the transmission gate circuitry, wherein a difference between the lowest value of the voltages from the pair of IO pins and the second protection voltage is less than or equal to the junction voltage limit, and wherein a difference between the highest value of the voltages from the pair of IO pins and the second protection voltage is less than or equal to the junction voltage limit.

14. The article of manufacture of claim 13, wherein the junction voltage limit of the transistors is 1.8V, the first protection voltage or the second protection voltage is between 1.5V and 1.8V, and the highest value of the voltages from the pair of IO pins is 3.3V.

15. The article of manufacture of claim 13, wherein configuring the transmission gate circuitry comprises applying the first protection voltage to the first voltage node between the first transistor and the second transistor, wherein the first transistor and the second transistor are NMOS transistors, and applying the second protection voltage to the second voltage node between the third transistor and the fourth transistor, wherein the third transistor and the fourth transistor are PMOS transistors.

16. Transmission gate circuitry to prevent aging stress on receiving circuitry by selectively blocking a voltage from an input/output (IO) pin from reaching a terminal of the receiver circuitry, the transmission gate circuitry comprising:
an NMOS path comprising NMOS transistors to which a first protection voltage is selectively applied at voltage nodes between the NMOS transistors to prevent a junction voltage difference between the NMOS transistors from exceeding a junction voltage limit; and
a PMOS path comprising PMOS transistors to which a second protection voltage is selectively applied at voltage nodes between the PMOS transistors to prevent a junction voltage difference between the PMOS transistors from exceeding the junction voltage limit.

17. The transmission gate circuitry of claim 16, wherein the NMOS path and the PMOS path couple to the IO pin on one end and to the terminal of the receiver circuitry on another end.

18. The transmission gate circuitry of claim 17, wherein:
the NMOS path comprises:
a first NMOS transistor coupled between the IO pin and a second NMOS transistor;
a third NMOS transistor coupled between the second NMOS transistor and the terminal of the receiver circuitry; and
a fourth NMOS transistor coupled between the first protection voltage and a first NMOS voltage node between the first NMOS transistor and the second NMOS transistor, wherein a gate of the fourth NMOS transistor is coupled to the IO pin; and
the PMOS path comprises:
a first PMOS transistor coupled between the IO pin and a second PMOS transistor;
a third PMOS transistor coupled between the second PMOS transistor and the terminal of the receiver circuitry; and
a fourth PMOS transistor coupled between the second protection voltage and a first PMOS voltage node between the first PMOS transistor and the second PMOS transistor, wherein a gate of the fourth PMOS transistor is coupled to the IO pin.

19. The transmission gate circuitry of claim 18, wherein:
the NMOS path comprises a fifth NMOS transistor coupled between the first protection voltage and a second NMOS voltage node between the second NMOS transistor and the third NMOS transistor, wherein a gate of the fifth PMOS transistor is coupled to the terminal of the receiver circuitry; and
the PMOS path comprises a fifth PMOS transistor coupled between the second protection voltage and a second PMOS voltage node between the second PMOS transistor and the third PMOS transistor, wherein a gate of the fifth PMOS transistor is coupled to the terminal of the receiver circuitry.

20. The transmission gate circuitry of claim 19, comprising pull-down transistors coupled in series between the first protection voltage and the terminal of the receiver circuitry, wherein the pull-down transistors are to provide the first protection voltage to the terminal of the receiver circuitry while the IO pin is in a single-ended communication state but not when the IO pin is in a low-voltage differential signaling (LVDS) state.
